(19) United States
(12) Patent Application Publication
(10) Pub. No.: US 2005/0121310 A1
(43) Pub. Date: Jun. 9, 2005

(54) Method and substrate to control flow of underfill

(75) Inventors: Atsushi Yamada, Ibaraki (JP); Hideki Goto, Ibaraki-ken (JP); Dennis Prem Kumar Chandran, Penang (MY); Leng Chee See, Penang (MY); Heng Gee Lee, Penang (MY)

Correspondence Address: FLESHNER & KIM, LLP, P.O. BOX 221200, CHANTILLY, VA, 20153, US

(73) Assignee: Intel Corporation

(21) Appl. No.: 10/725,449

(22) Filed: Dec. 3, 2003

(51) Int. Cl. C23C 14/32

(52) U.S. Cl. 204/192.12; 204/298.11

(57) ABSTRACT

A selective sputtering method and resulting substrate are provided. This may involve obtaining a substrate and identifying a die placement area and a keep out area of the substrate. A protective area may be formed over the substrate between the die placement area and the keep out area. This may be done using a selective sputtering process. Underfill material may be provided over at least the die placement area of the substrate without the underfill material flowing to the keep out area based on the surface roughness of the keep out area.

### FIELD

Embodiments of the present invention may relate to controlling the flow of materials over a substrate. More particularly, embodiments of the present invention may relate to reducing the flow of an underfill material used to attach a silicon die to a substrate.

### BACKGROUND

Integrated circuits are typically assembled into packages (or package assemblies) that are mounted to a printed circuit board. The package may include a substrate that has solder balls or other types of contacts that are attached to the circuit board. An integrated circuit is mounted to the substrate. The integrated circuit (IC) may be connected to corresponding surface pads of the substrate with solder bumps in a process commonly referred to as controlled collapsed chip connection (C4). The substrate typically has routing traces, vias, etc. that electrically connect the integrated circuit to the solder balls.

Packages may contain an underfill material that is formed between the integrated circuit and the substrate. The underfill material structurally reinforces the solder bumps and improves the life and reliability of the package. The underfill material is typically dispensed onto the substrate in a liquid or semi-liquid form. The liquid underfill then flows between the integrated circuit and the substrate under a capillary action. The liquid underfill is eventually cured into a solid state. The underfill process fills the space between the integrated circuit and the substrate to structurally reinforce all of the solder bumps.

### BRIEF DESCRIPTION OF THE DRAWINGS

The foregoing and a better understanding of the present invention will become apparent from the following detailed description of arrangements and example embodiments (and the claims) when read in connection with the accompanying drawings, all forming a part of the disclosure of this invention. While the foregoing and following written and illustrated disclosure focuses on disclosing arrangements and example embodiments of the invention, it should be clearly understood that the same is by way of illustration and example only and the invention is not limited thereto.

The following represents brief descriptions of the drawings in which like reference numerals represent like elements and wherein:

FIG. 1 is a side view of a package assembly according to an example arrangement;

FIG. 2 is a top view of a package assembly according to an example arrangement;

FIG. 3 is a top view of a package assembly according to an example arrangement;

FIG. 4 is a side view of a package assembly according to an example arrangement;

FIG. 5 is a top view of a package assembly according to an example arrangement;

FIG. 6 is a top view of a package assembly according to an example embodiment of the present invention;

FIG. 7 is a side view of a package assembly according to an example embodiment of the present invention;

FIG. 8 is a close-up side view of a package assembly (showing surface roughness) according to an example embodiment of the present invention;

FIG. 9 shows side and top views of the formation of a protective area according to an example embodiment of the present invention;

FIG. 10 shows a substrate and corresponding surface roughness according to an example arrangement;

FIG. 11 shows a substrate and different surface roughness according to an example embodiment of the present invention; and

FIG. 12 is a flowchart showing operations according to an example embodiment of the present invention.

### DETAILED DESCRIPTION

In the following detailed description, like reference numerals and characters may be used to designate identical, corresponding or similar components in differing figure drawings. Further, in the detailed description to follow, example sizes/models/values/ranges may be given although the present invention is not limited to the same. Where specific details are set forth in order to describe example embodiments of the invention, it should be apparent to one skilled in the art that the invention can be practiced without these specific details.

In the following description, the terminology substrate may be used to describe a material to support a die or integrated circuit. This substrate may or may not include various layers, including a solder resist layer. That is, these various layers including the solder resist layer may be considered as part of the substrate.

Embodiments of the present invention may provide a method of forming a package assembly that involves obtaining a substrate and identifying a die placement area and a keep out area of the substrate. A protective area of the substrate may be identified between the die placement area and the keep out area A mask may be provided over the substrate to allow selective sputtering over the substrate. That is, areas corresponding to the protective area may receive little or no sputtering due to the mask, whereas areas corresponding to the die protective area may receive sputtering (such as by O2 plasma or H2 plasma). Thus, the area corresponding to the protective area may have a smoother roughness than the area corresponding to the die placement area. Underfill material may subsequently be applied at the die placement area. The area having the smoother roughness (at the protective area) may prevent overflow of the underfill material to the keep out area.

Various arrangements and embodiments of the present invention will now be described with respect to the respective figures.

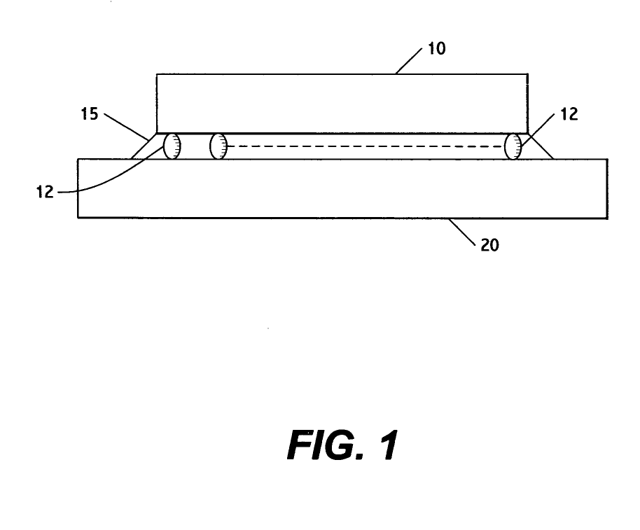

FIG. 1 is a side view of a package assembly according to an example arrangement. Other arrangements are also possible. More specifically, FIG. 1 shows a type of integrated circuit package that is commonly referred to as a flip chip or C4 package. The package assembly may contain a die 10 (or integrated circuit) mounted on a substrate 20. A plurality of solder bumps 12 may be soldered to a top surface of the substrate 20.

The package may include an underfill material 15 that is located between the die 10 and the substrate 20. The underfill material 15 may be an epoxy that strengthens the solder joint reliability and the thermo-mechanical moisture stability of the IC package.

The package may have hundreds of solder bumps 12 arranged in a two dimensional array across the bottom of the die 10. The underfill material 15 may be applied to the solder bump interface by dispensing an uncured epoxy material along a side of the die 10. The underfill material 15 may then flow between the solder bumps 12 based on capillary action. The underfill material 15 is dispensed in a manner that covers all of the solder bumps 12. Other methods of applying the underfill material may also be performed.

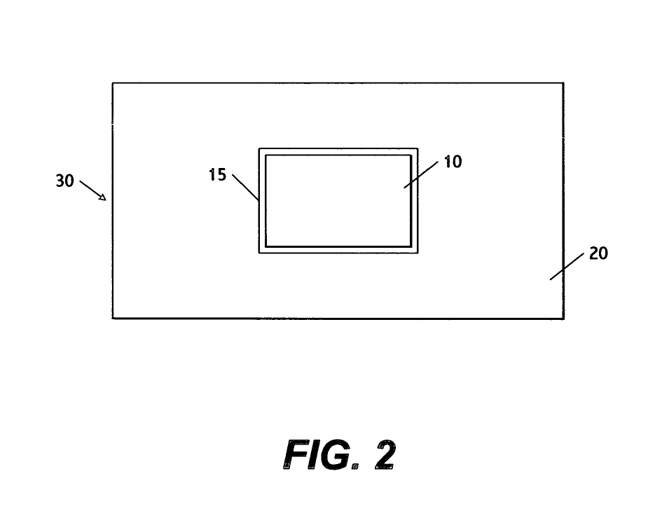

FIG. 2 is a top view of a package assembly according to an example arrangement. Other arrangements are also possible. As shown, a package 30 may include the substrate 20 and the die 10 attached by the plurality of solder bumps (not specifically shown in FIG. 2). The solder bumps may be arranged in a two-dimensional array across the die 10. The solder bumps may be attached to the die 10 and to the substrate 20 by a process commonly referred to as controlled collapse chip connection (C4).

The solder bumps may carry electrical current between the die 10 and the substrate 20. The substrate 20 may include an organic dielectric material. The package 30 may also include a plurality of solder balls (not shown) attached to a bottom surface of the substrate 20. These solder balls can be reflowed to attach the package 30 to a printed circuit board (not shown).

The substrate 20 may also contain routing traces, power/ground planes, vias, etc. (not shown) that electrically connect with the solder bumps 12. The die 10 may be encapsulated by an encapsulant (not shown). Additionally, the package 30 may incorporate a thermal element (not shown) such as a heat slug or a heat sink to remove heat generated by the die 10.

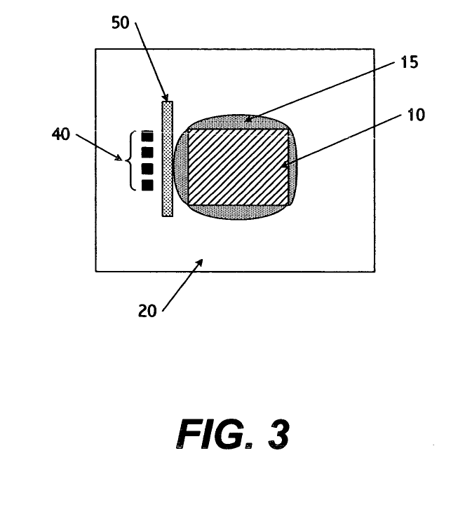

FIG. 3 is a top view of a package assembly according to an example arrangement. Other arrangements are also possible. More specifically, FIG. 3 shows the die 10 mounted on the substrate 20. The package assembly may also include solder lands 40 that later will be connected to passive electrical components such as capacitors (not shown). As shown, the underfill material 15 may be applied in a liquid form to flow between the solder bumps 12 and a die attachment location (or die perimeter) on the substrate 20. The die 10 is assembled to the substrate 20 and excess underfill material 15 may flow out from between the die 10 and the substrate 20. This excess underfill material may be referred to as overflow of the underfill material. However, in disadvantageous arrangements the overflow of the underfill material 15 may flow to cover the solder lands 40 on the substrate 20. To preclude the covering of these solder lands 40, the package may include a keep out area (or zone) for die side passive electrical component placement. As one example, a solder resist trench 50 may be formed between the die 10 and the solder lands 40 in order to reduce or eliminate the underfill material 15 from covering the solder lands 40.

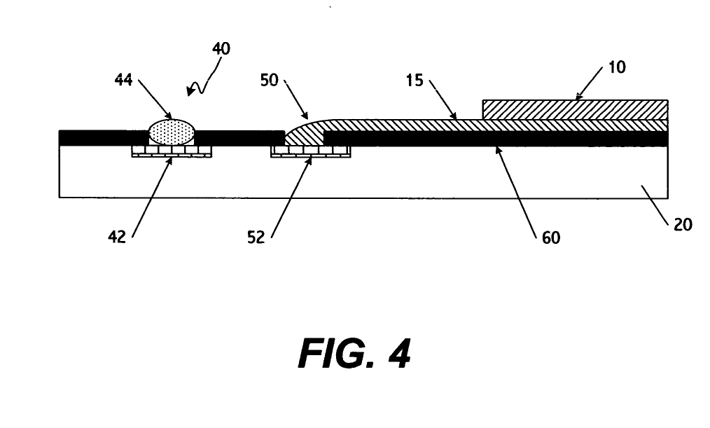

FIG. 4 is a side view of a package assembly according to an example arrangement. Other arrangements are also possible. More specifically, FIG. 4 shows the underfill material 15 provided between the die 10 and the substrate 20.

FIG. 4 also shows a solder resist 60 on a top surface of the substrate 20. The solder resist 60 is a coating material used to mask or protect selected areas from the action of an etchant, solder or plating. A metal pad 52 may be provided under the solder resist trench 50. The metal pads 52 act to protect lower layers/pads of the substrate 20. The solder lands 40 provided in the keep out area may also include metal pads (such as a metal pad 42) that electrically connect with underlying elements of the substrate 20. FIG. 4 also shows pre-solder 44 provided over the metal pad 42. The pre-solder 44 is provided for making electrical contact with the passive electrical components, such as capacitors, that will be subsequently placed on the substrate.

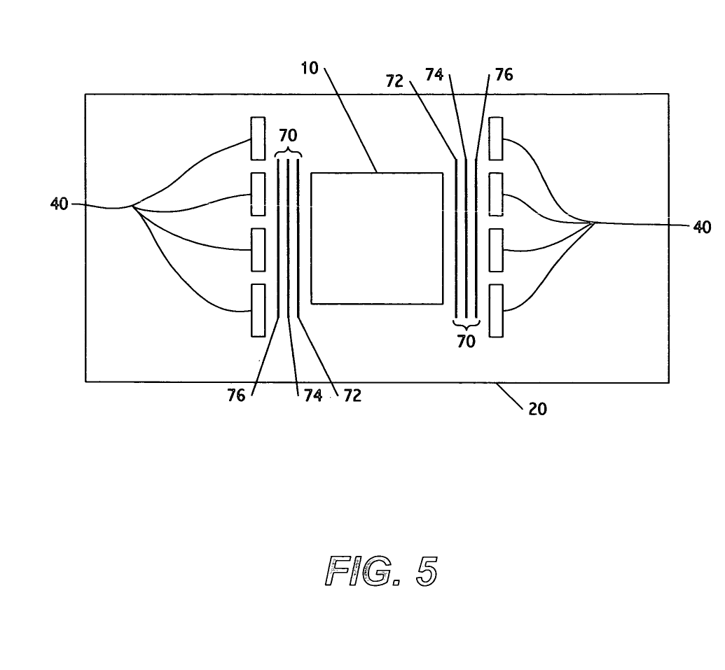

FIG. 5 is a top view of a package assembly according to an example arrangement. Other arrangements are also possible. This arrangement includes two barriers 70, each made with three barrier elements, in order to prevent overflow of the underfill material 15 to the solder lands 40. Each of the barriers 70 may include a trench barrier element 72 (trench) constructed with solder masking (not shown), and two dams 74 and 76 each constructed from silk-screen ink, for example. The barriers 70 may restrict the flow of the underfill material 15 and as a result, allows for the placement of the solder lands (or passive component lands) 40 closer to the die 10. Both solder mask trenches 72 and ink dams 74, 76 can be formed at the same time other features are formed. The ink dams 74, 76 may be the same dimensions and type of ink used for standard ink markings and the solder masking trenches 72 may follow standard design rules for depth and opening size.

The flow of the underfill material 15 may first contact the trench 72 and the underfill material 15 can spread out in a direction of the length of the trench 72. The underfill material 15 that flows across (or breaches) the trench 72 may contact the dam 74 that will further direct flow along the direction of the length of the dam 74. The underfill material 15 that breaches the dam 74 may contact the dam 76. The dam 76 can further deflect flow along the length of the dam 76 as well as along the length of the trench etched within the dam 76.

Other structures and methodologies for protecting the flow of overfill material will now be described. These methodologies and structures may relate to surface roughness. A rougher surface topology may be important for smoothly filling the underfill material 15 under the die 10 by capillary action. That is, the capillary action of the underfill material 15 performs better for a rougher surface than a smoother surface. O2 plasma may be used (at a substrate supplier, for example) to roughen the surface as well as for cleaning organic residue. However, when the O2 plasma may be applied over the surface of the solder resist 60 or the substrate 20, the surface topology is relatively homogeneous. Substrates with a homogenous surface topology may have inconsistent underfill filet formation from substrate to substrate after dispensing and curing the underfill material.

Embodiments of the present invention may provide selective roughening (i.e., no or less roughening at a protective area close to the keep out area) on the solder resist/substrate. The selective roughening may produce a consistent fillet area to avoid improper fillet formation. This may help avoid issues such as overflow to the keep out area, dendrites, Insufficient Die Edge Coverage (IDEC) and butterfly shape filleting (top view) that was not completely filed in the gap between a die (IC) and a substrate.

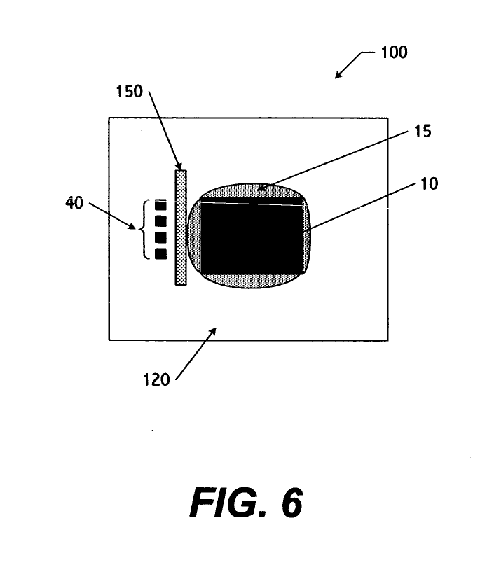

FIG. 6 is a top view of a package assembly according to an example embodiment of the present invention. Other embodiments and configurations are also within the scope of the present invention. More specifically, FIG. 6 shows a package 100 that may include the die (or integrated circuit) 10 mounted on a substrate 120. Although not specifically shown in FIG. 6, the die 10 may be mounted to the substrate 120 by a plurality of solder bumps (such as solder bumps 12 shown in FIG. 1). As shown, the underfill material 15 may be applied in a liquid form to flow between the solder bumps and a die attachment location (or die perimeter) on the substrate 120. The die 10 may be assembled to the substrate 120 and the excess underfill material 15 may flow out from between the die 10 and the substrate 120 in a similar manner as discussed above. FIG. 6 further includes a protective area 150 to prevent or minimize the flow of the underfill material 15 from reaching the keep out area (or zone) for die side passive electrical component placement (i.e., the area of the solder lands 40). As will be described below, the protective area 150 may correspond to an area on the substrate 120 having a different smoothness (i.e., less roughness than other areas). This area may be formed by having less or no sputtering on the surface of the substrate 120 as compared with other surface areas of the substrate 120.

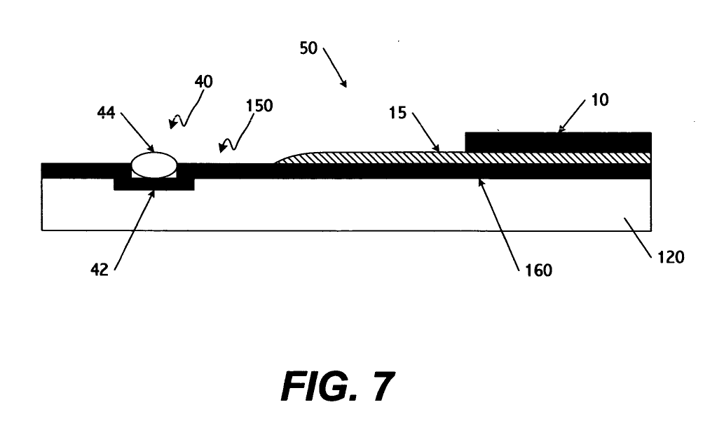

FIG. 7 is a side view of a package assembly according to an example embodiment of the present invention. Other embodiments and configurations are also within the scope of the present invention. More specifically, FIG. 7 shows the underfill material 15 provided between the die 10 and the substrate 120. FIG. 7 also shows a solder resist 160 on a top surface of the substrate 120. The solder resist 160 is a coating material used to mask or protect selected areas from the action of an etchant, solder or plating. The solder lands 40 provided in the keep out area may include metal pads (such as a metal pad 42) that electrically connect with underlying elements of the substrate 120. FIG. 7 also shows pre-solder 44 for making electrical contact with the passive electrical components, such as capacitors. The protective area 150 provided between the integrated circuit 110 and the solder lands 40 helps prevent the overflow of the underfill material 15 from reaching (or flowing into) the keep out area of the solder lands 40.

Embodiments of the present invention may utilize selective sputtering (or selective chemical etching) on the surface of the substrate 120 (or more specifically on the surface of the solder resist 160). The selective sputtering may be applied to (or over) the protective area 150 to avoid the underfill material from overflowing to the keep out area. This may be accomplished without sacrificing a higher density design. Selective sputtering may be accomplished using masking materials to avoid sputtering on a particular area. Selective sputtering may also be accomplished by printing (or providing) some materials (e.g. resist, ink or other organic material) on the particular area and sputtering in a normal manner. Thus, only the printed material is sputtered at the selective area rather than the substrate/solder resist. The original surface of the substrate/solder resist is sputtered normally.

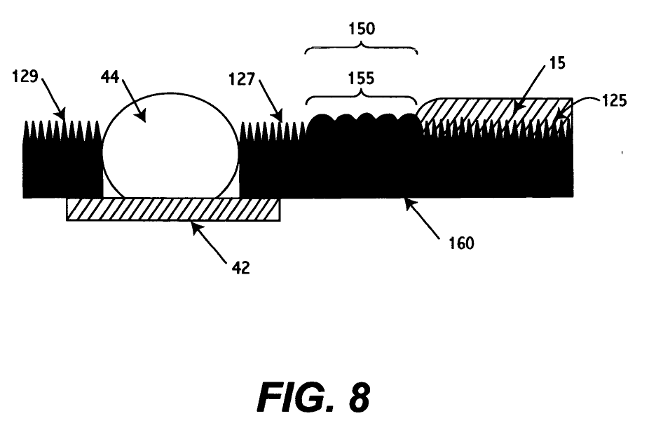

FIG. 8 is a close-up side view of a package assembly (showing surface roughness) according to an example embodiment of the present invention. Other embodiments and configurations are also within the scope of the present invention. More specifically, FIG. 8 shows different surface areas of the substrate 120 after the selective sputtering. That is, the protective area 150 of the solder resist 160 may have a smoother surface area 155 as compared to area 125 of the solder resist 160 having a rougher surface area. Other areas 127 and 129 of the solder resist 160 may also have the rougher surface area than the smoother surface area 155 of the protective area 150.

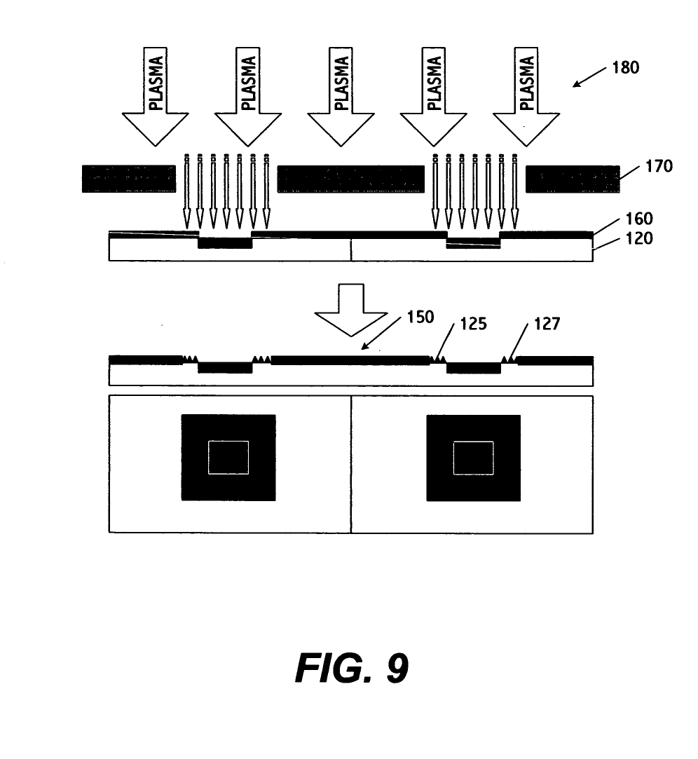

FIG. 9 shows side and top views of the formation of the protective area according to an example embodiment of the present invention. Other embodiments and configurations are also within the scope of the present invention. These two views are shown to provide both a top perspective and a side perspective of the package assembly. More specifically, FIG. 9 shows a mask 170 provided over the substrate 120 and the solder resist 160. The mask 170 may be used to block 02 plasma 180 that is directed toward the surface of the solder resist 160 and the substrate 120. The O2 plasma causes sputtering on the surface of the solder resist 160. Thus the mask 170 provides a protective area 150 on the solder resist 160 for areas that are not irradiated with the O2 plasma (i.e., no or little sputtering).

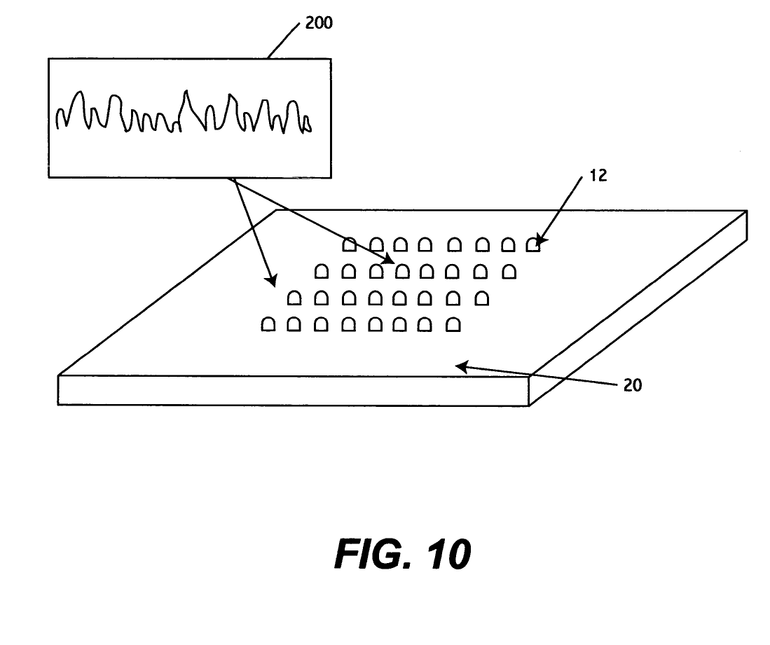

FIG. 10 shows a substrate and surface roughness according to an example arrangement. More specifically, FIG. 10 shows various solder bumps (such as solder bumps 12) on the surface of the substrate 20 (which may include the solder resist). Due to the uniform sputtering over the substrate 20, a rough surface topology 200 may be provided across the surface of the substrate 20.

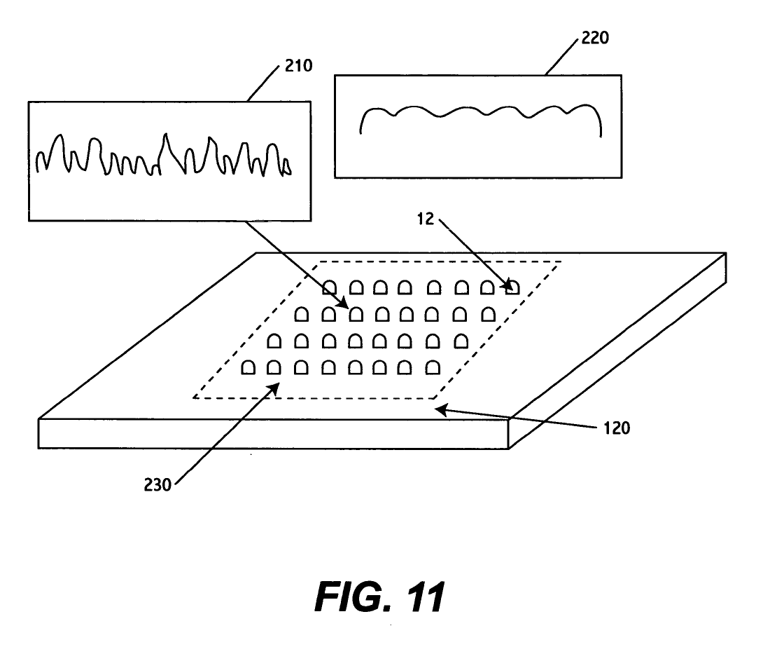

On the other hand, FIG. 11 shows a substrate and different surface roughness according to an example embodiment of the present invention. In this embodiment, selective sputtering occurs so that one roughness is provided in a first area and a second roughness is provided in a second area, as discussed above. As shown, the substrate 120 may have a rough surface topology 210 over areas that received the sputtering process and a smoother surface topology 220 over areas that received less of a sputtering process (or no sputtering). In this figure, area 230 corresponds to an area to receive underfill such as the area for die placement.

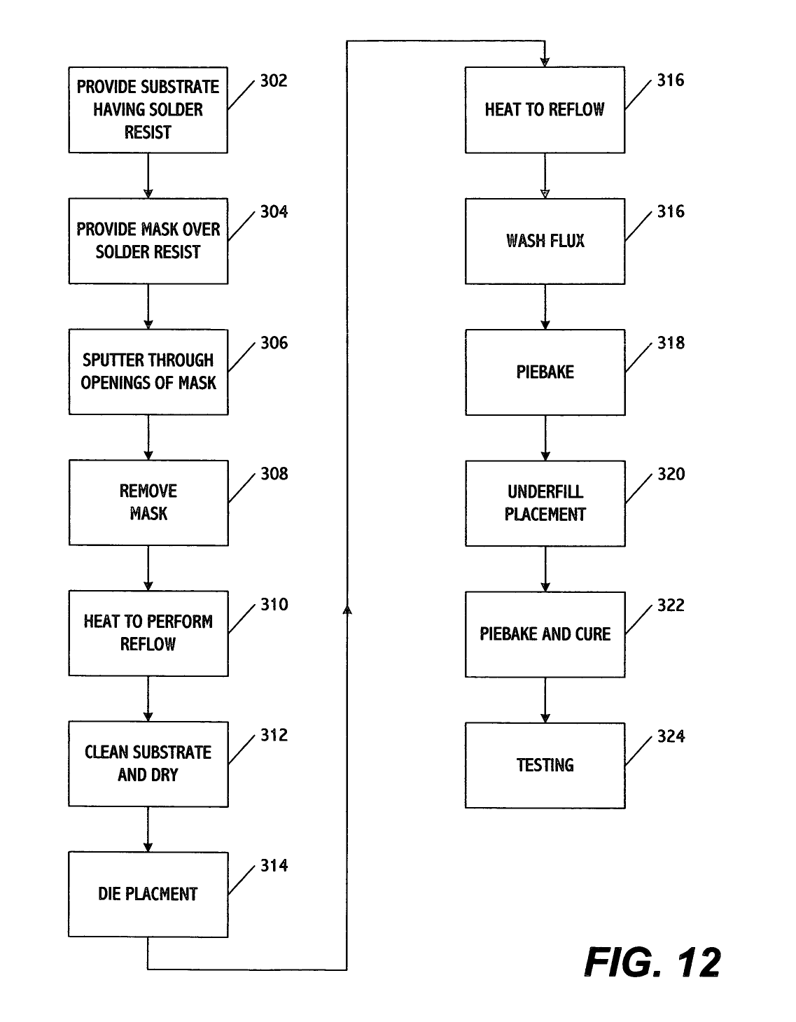

FIG. 12 is a flowchart showing operations according to an example embodiment of the present invention. Other operations, orders of operations and embodiments are also within the scope of the present invention. More specifically, in block 302, a substrate having a solder resist may be provided. The solder resist coating may be applied through a process of curing, exposure and development. The substrate may have different areas identified such as a die placement area, a keepout area and a protective area. A mask may be provided over the solder resist in block 304 such that the areas that are to receive little or no sputtering are masked. A roughening of the surface by sputtering (or chemical process) may then occur through openings of the solder resist in block 306. That is, selective sputtering (or chemical etching) as discussed above may occur in block 306. The mask may be removed in block 308.

Various operations may then occur before die placement. For ease of illustration, not all of these operations are shown. FIG. 12 does show that the assembly may be heated in block 310, and the substrate may be cleaned and dried in block 312.

In block 314, the die may be placed onto the die placement area of the substrate. The assembly may be heated to perform reflow in block 316 and flux may be washed (or defluxed) in block 316. The assembly may then be pre-baked in block 318. In block 320, the underfill material may be provided (or injected) between the die and the substrate. Pre-bake and curing may occur in block 322. The assembly may be electrically tested in block 324. Upon proper testing, the assembly may be appropriately sold or used.

Embodiments of the present invention may optimize the underfill process to eliminate or reduce the occurrence of underfill related defects (such as overflow to the keep out area, underfill dendrites and/or butterfly shape filleting that was not completely filled in the gap between a die (IC) and a substrate). This may also allow less space between the die area and the keep out area. Thus, high density capacitors (Die Side Chip (DSC) capacitors) may be placed closer to the die area. This may also provide a cost savings because no additional metal traces are necessary such as in solder resist trenches. Additionally, embodiments of the present invention may help avoid issues related to the printing pre-solder paste for the die side chip capacitors to avoid pre-solder stretch.

While embodiments of the present invention have been described with respect to O2 plasma being used for sputtering, other techniques are also within the scope of the present invention. For example, H2 plasma may also be used. Additionally, chemical etching may also be used. Still further, embodiments of the present invention may also achieve a smoother surface topology by using additional sputtering (or additional chemical etching).

Additionally, embodiments of the present invention may be provided within one or more component packages, such as integrated circuit packages, which can be physically and electrically coupled to a printed circuit board to form an electrical assembly. The term electrical assembly may be part of an electronic system. An electronic system may be any product including an electronic assembly. Examples of electronic systems include computers (e.g. desktop, laptop, hand-held, server, etc.), wireless communications devices (e.g. cellular phone, cordless phones, pagers, etc.), computer-related peripherals (e.g., printers, scanners, monitors, etc.), entertainment devices (e.g. televisions, radios, stereos, tap and compact disc players, video cassette recorders, MP3 (Motion Picture Experts Group, Audio Layer 3) players, etc.), and the like.

Additionally, while embodiments have been described with respect to integrated circuits mounted on an integrated substrate, embodiments of the present invention are not limited only to such applications, as it may be used for other types of electronic packages and other types of components, such as passive components, hybrid modules, printed circuit boards, mezzanine boards, and for any other type of electrical structure requiring underfill.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments. Furthermore, for ease of understanding, certain method procedures may have been delineated as separate procedures; however, these separately delineated procedures should not be construed as necessarily order dependent in their performance. That is, some procedures may be able to be performed in an alternative ordering, simultaneously, etc.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

1. A method comprising:
selecting a protective area of a substrate;
providing a first surface roughness over a first area of a substrate; and
providing a second surface roughness over the selected protective area of the substrate, the second surface roughness being different than the first surface roughness.

2. The method of claim 1, wherein selecting the protective area comprises determining an area in which to prevent overflow of underfill material.

3. The method of claim 1, wherein providing the first surface roughness and providing the second surface roughness comprises performing a sputtering process over the surface of the substrate using a mask.

4. The method of claim 3, wherein the sputtering process provides less sputtering to the protective area than the first area.

5. The method of claim 3, wherein the sputtering process comprises an oxygen plasma sputtering process.

6. The method of claim 3, wherein the sputtering process comprises a hydrogen plasma sputtering process.

7. The method of claim 1, wherein providing the first surface roughness and providing the second surface roughness comprises performing a chemical etching over the substrate.

8. The method of claim 1, further comprising providing an underfill material over the first area of the substrate.

9. The method of claim 1, wherein the protective area is selected to avoid underfill overflow into a particular area of the chip.

10. The method of claim 1, further comprising attaching a die over the first area of the substrate.

11. The method of claim 10, further comprising providing underfill material between the die and the substrate without overflowing the underfill material over all of the protective area.

12. The method of claim 1, wherein the substrate includes a solder resist.

13. A method comprising:
obtaining a substrate;
identifying a die placement area and a keep out area of the substrate;
forming a protective area over the substrate between the die placement area and the keep out area; and
flowing an underfill material over at least the die placement area of the substrate and preventing the underfill material from flowing over the protective area based on surface roughness.

14. The method of claim 13, wherein forming the protective area comprises:
providing a first surface roughness over the die placement area of a substrate; and
providing a second surface roughness over the protective area of the substrate, the second surface roughness being different than the first surface roughness.

15. The method of claim 14, wherein providing the first surface roughness and providing the second surface roughness comprises performing a sputtering process over the surface of the substrate using a mask.

16. The method of claim 15, wherein the sputtering process provides less sputtering to the protective area than the die placement area.

17. The method of claim 15, wherein the sputtering process comprises an oxygen plasma sputtering process.

18. The method of claim 15, wherein the sputtering process comprises a hydrogen plasma sputtering process.

19. The method of claim 14, wherein providing the first surface roughness and providing the second surface roughness comprises performing a chemical etching over the substrate.

20. The method of claim 13, further comprising attaching a die over the die placement area of the substrate.

21. The method of claim 20, wherein flowing the underfill material comprises flowing the underfill material between the die and the die placement area of the substrate.

22. The method of claim 13, wherein the underfill material flows in the die placement area without flowing to the keep out area based on the surface roughness of the die placement area and the surface roughness of the protective area.

23. The method of claim 13, wherein the protective area is selected to avoid underfill overflow into the keep out area of the substrate.

24. The method of claim 13, wherein the substrate includes a solder resist.

25. An apparatus comprising:
a substrate having a die placement area and a keep out area, the substrate having a first surface roughness over the die placement area and a second roughness over a protective area between the die placement area and the keep out area.

26. The apparatus of claim 25, wherein the second roughness is selected to prevent overflow of underfill to the keep out area.

27. The apparatus of claim 25, further comprising a die attached over the die placement area.

28. The apparatus of claim 25, further comprising underfill material provided between the die and the substrate in the die placement area without the overfill material provided within the keep out area.

29. The apparatus of claim 25, wherein the substrate comprises a printed circuit board.

30. The apparatus of claim 25, further comprising a passive electrical element provided in the keep out area.
